(19) United States
(12) Patent Application Publication
(10) Pub. No.: US 2011/0053799 A1
(43) Pub. Date: Mar. 3, 2011

(54) METHOD OF PRODUCING MICROARRAY SUBSTRATE, RADIATION-SENSITIVE COMPOSITION, PARTITION OF MICROARRAY SUBSTRATE, METHOD OF PRODUCING BIOCHIP, AND BIOCHIP

(75) Inventors: Satoko ABIKO, Tokyo (JP); Hirofumi Goto, Tokyo (JP); Hazuki Takamura, Tokyo (JP); Satoshi Ishikawa, Tokyo (JP)

(73) Assignee: JSR Corporation, Tokyo (JP)

(21) Appl. No.: 12/869,759

(22) Filed: Aug. 27, 2010

(30) Foreign Application Priority Data
Aug. 31, 2009 (JP) 2009-200922
Feb. 22, 2010 (JP) 2010-36631
Aug. 6, 2010 (JP) 2010-177916
Aug. 6, 2010 (JP) 2010-177917

(51) Int. Cl. C40B 40/00; B32B 3/10; G03F 7/004; G03F 7/20; C40B 40/06; C40B 40/10; C40B 40/12; C40B 50/18

(52) U.S. Cl. 506/13; 428/195.1; 430/283.1; 430/320; 506/16; 506/18; 506/19; 506/32; 506/15

(57) ABSTRACT

A method is of producing a microarray substrate that includes a substrate, a partition that is formed on a surface of the substrate, and an area that is positioned over the substrate and defined by the partition. The method includes forming a first film on the substrate using a radiation-sensitive composition. The radiation-sensitive composition includes a coloring agent (A) including at least one of a violet pigment (a2) and a compound (a1) shown by a formula (1) in which each of R¹ and R² represents one of a hydrogen atom, a halogen atom, an alkyl group having 1 to 10 carbon atoms, a perfluoroalkyl group having 1 to 10 carbon atoms, and an amino group having 0 to 5 carbon atoms. The first film is patterned by lithography to form the partition.

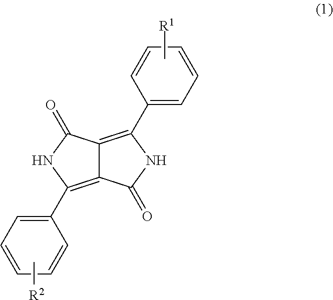

### CROSS-REFERENCE TO RELATED APPLICATION

The present application claims priority to Japanese Patent Application No. 2009-200922 filed Aug. 31, 2009, Japanese Patent Application No. 2010-36631 filed Feb. 22, 2010, Japanese Patent Application No. 2010-177916 filed Aug. 6, 2010 and Japanese Patent Application No. 2010-177917 filed Aug. 6, 2010. The contents of these applications are incorporated herein by reference in their entirety.

### BACKGROUND OF THE INVENTION

1. Field of the Invention

The present invention relates to a method of producing a microarray substrate, a radiation-sensitive composition, a partition of a microarray substrate, a method of producing a biochip, and a biochip.

2. Discussion of the Background

In recent years, a microarray has attracted attention as a device that measures or utilizes the interaction or reaction between a probe molecule (e.g., nucleic acid, protein, peptide, sugar chain, low-molecular-weight compound, cell, or tissue) provided on a substrate and a biological substance (i.e., target molecule). A substrate (microarray substrate) that includes a plurality of reaction areas (cavities) for immobilizing the probe molecule is used for such a microarray. For example, a biochip in which a target substance (e.g., biological substance (e.g., DNA, protein, or sugar chain)) is densely provided (partitioned) on the surface of a substrate, has been known. A number of samples can be simultaneously processed by utilizing such a biochip. Attempts have been made to increase the density in order to obtain more information by a single process.

A number of target substances may be placed on the surface of the microarray substrate by synthesizing the target substance on the substrate, or adding the target substance dropwise to the surface of the substrate, for example. When adding the target substance dropwise to the surface of the substrate, a solution prepared by dissolving the target substance is added dropwise to a given area of the substrate, and the target substance is immobilized, for example.

Related-art technology is disclosed in Japanese Patent Application Publication (KOKAI) No. 2005-214889, WO06/101229, and Japanese Patent Application Publication (KOKAI) No. 2001-343385, for example.

The biochip may be used as a substrate for a sequencing agent that detects the base sequence of a nucleic acid or the like. A base sequence may be detected by amplifying a biological substance on the biochip utilizing a polymerase chain reaction (PCR), and utilizing fluorescence (label) emitted from the biological substance (see Japanese Patent Application Publication (KOKAI) No. 2006-320307 and WO07/048033).

It is known that the interaction or reaction between a probe molecule and a target molecule may be detected by detecting fluorescence emitted due to the interaction or reaction between the probe molecule and the target molecule optionally using a fluorescent label or the like. When using a fluorescent label, induced light may be applied to the entire microarray, and fluorescence emitted from each cavity may be received using a measuring instrument to detect the presence or absence (or state) of the reaction (see Japanese Patent Application Publication (KOKAI) No. 2005-214889, WO06/101229, Japanese Patent Application Publication (KOKAI) No. 2001-343385, Japanese Patent Application Publication (KOKAI) No. 2006-320307, and WO07/048033).

A microarray such as a biochip is normally formed to obtain information about a reaction that occurs in each cavity defined by a partition by utilizing a fluorescent label or the like. For example, when using a fluorescent label, induced light is applied to the entire biochip, and fluorescence emitted from each cavity is received using a measuring instrument to detect the presence or absence (or state) of the reaction.

However, a problem may occur due to color mixture of fluorescence emitted from each cavity along with an increase in density. Specifically, the cavities may not be sufficiently optically isolated due to a decrease in thickness of the partition along with an increase in density. The cavities may be optically isolated by adding a component (e.g., light absorber) that has an absorption band in the measurement light region. However, properties originally required for the partition may deteriorate due to the addition of such a component.

### SUMMARY OF THE INVENTION

According to one aspect of the present invention, a method is of producing a microarray substrate that includes a substrate, a partition that is formed on a surface of the substrate, and an area that is positioned over the substrate and defined by the partition. The method includes forming a first film on the substrate using a radiation-sensitive composition. The radiation-sensitive composition includes a coloring agent (A) including at least one of a compound (a1) shown by a formula (1) and a violet pigment (a2). The first film is patterned by lithography to form the partition.

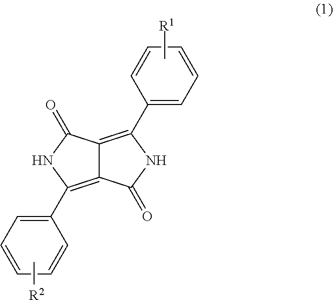

wherein each of R¹ and R² represents one of a hydrogen atom, a halogen atom, an alkyl group having 1 to 10 carbon atoms, a perfluoroalkyl group having 1 to 10 carbon atoms, and an amino group having 0 to 5 carbon atoms.

According to another aspect of the present invention, a radiation-sensitive composition is used to form a partition of a microarray substrate that includes a substrate, a partition that is formed on a surface of the substrate, and an area that is positioned over the substrate and defined by the partition. The radiation-sensitive composition includes a coloring agent (A) including at least one of a compound (a1) shown by a formula (1) and a violet pigment (a2).

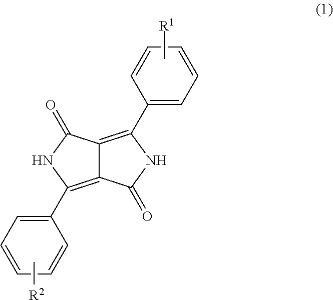

wherein each of R¹ and R² represents one of a hydrogen atom, a halogen atom, an alkyl group having 1 to 10 carbon atoms, a perfluoroalkyl group having 1 to 10 carbon atoms, and an amino group having 0 to 5 carbon atoms.

According to still another aspect of the present invention, a partition of a microarray substrate is produced using the above-described radiation-sensitive composition.

According to yet still another aspect of the present invention, a method of producing a biochip includes producing a microarray substrate using the above-described method. An immobilizing substance configured to immobilize a target substance is placed in an area of the microarray substrate. The target substance is immobilized on the immobilizing substance.

According to another aspect of the present invention, a method of producing a biochip includes producing a microarray substrate using the above-described method. A carrier substance is placed in an area of the microarray substrate. The carrier substance carries a target substance on a surface of the carrier substance.

According to the other aspect of the present invention, a biochip is produced by the above-described method of producing a biochip.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a perspective view schematically showing a microarray substrate (pre-biochip);

FIG. 2 is a plan view schematically showing a microarray substrate (pre-biochip);

FIG. 3 is a schematic view illustrative of a method of producing a microarray substrate;

FIG. 4 is a schematic view illustrative of a first method of producing a biochip; and

FIG. 5 is a schematic view illustrative of a second method of producing a biochip.

### DESCRIPTION OF THE EMBODIMENTS

The invention is described in detail below. Note that the term “(meth)acryl” used herein refers to acryl and methacryl, and the term “(meth)acrylate” used herein refers to an acrylate and a methacrylate.

### [1] Method of Producing Microarray Substrate

A method of producing a microarray substrate according to one embodiment of the invention is used to produce a microarray substrate that includes a substrate (i.e., a substrate that forms the microarray substrate), a partition that is formed on a surface of the substrate, and an area that is positioned over the substrate and defined by the partition, the method including forming a first film on the substrate using a radiation-sensitive composition that includes (A) at least one coloring agent selected from (a1) a compound shown by the formula (1) and (a2) a violet pigment (hereinafter may be referred to as “first film-forming step”), and patterning the first film by lithography to form the partition (hereinafter may be referred to as “partition-forming step”).

When forming the partition of the microarray substrate using the compound shown by the formula (1), light having a desired wavelength (500 to 600 nm) can be efficiently blocked by the partition. Therefore, the areas (cavities) defined by the partition can be reliably optically isolated. The compound shown by the formula (1) exhibits a high blocking effect even when adding only a small amount of the compound. Therefore, the amount of the compound shown by the formula (1) added to the radiation-sensitive composition can be reduced, so that the partition exhibits sufficient adhesion to the substrate. In particular, since a resin component that increases the adhesion of the partition to the substrate can be sufficiently added to the radiation-sensitive composition, the adhesion of the partition to the substrate can be improved.

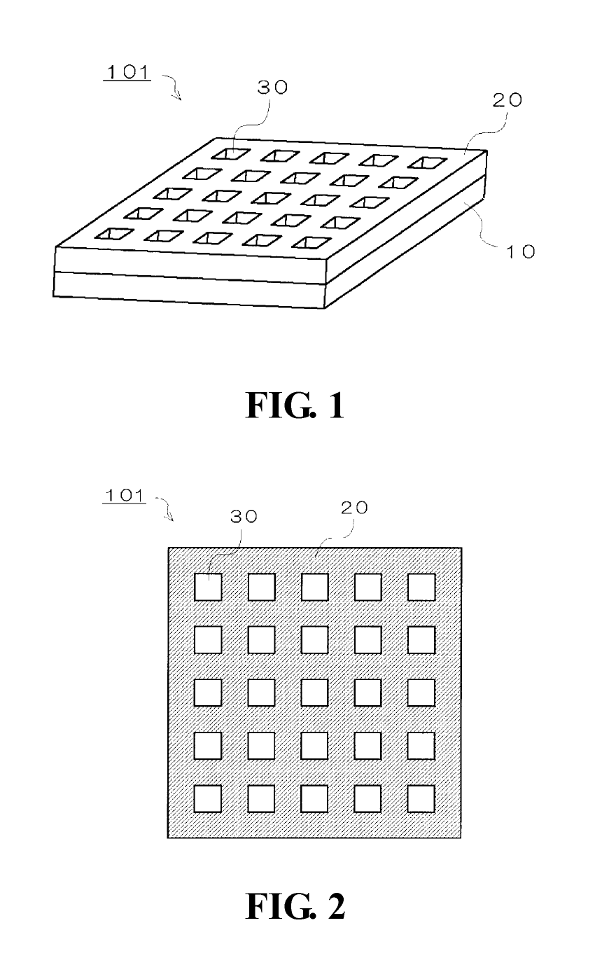

As shown in FIGS. 1 to 5, a partition 20 is formed on the surface of a substrate 10. A cavity 30 that is surrounded by the partition 20 is formed in each area defined by the partition 20.

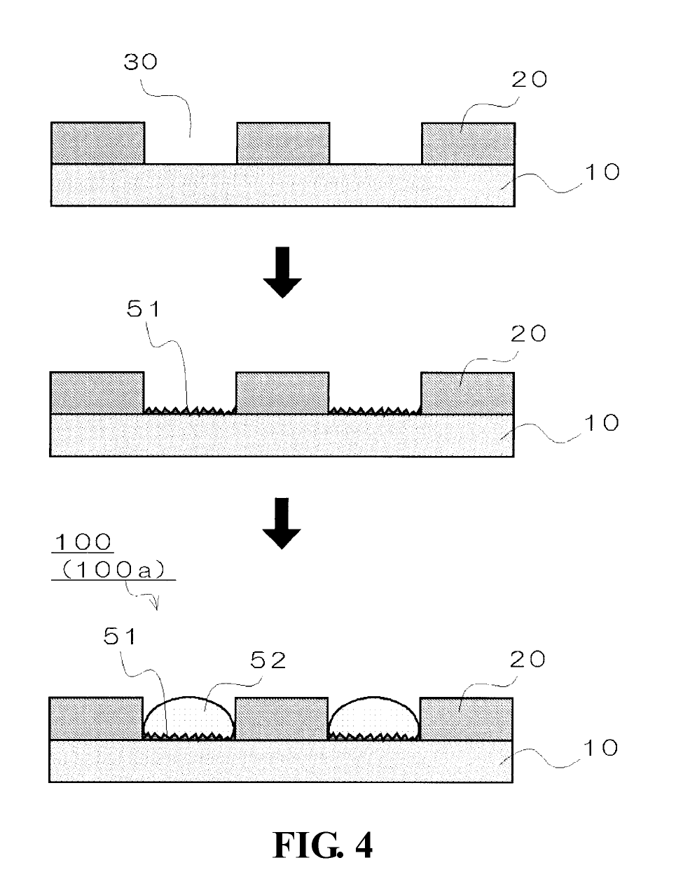

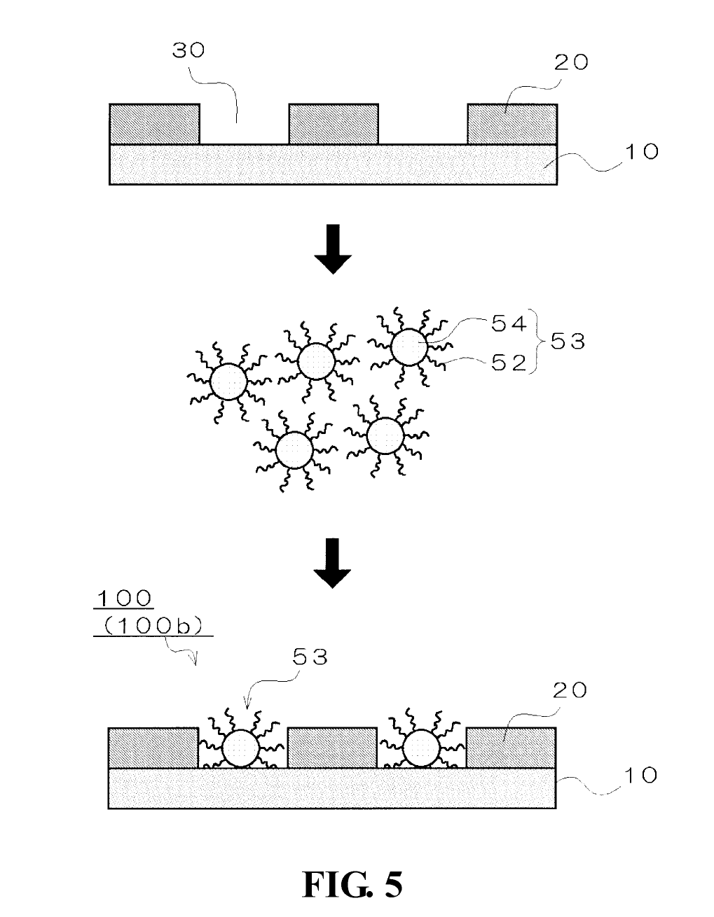

A biochip 100 according to one embodiment of the invention is a chip 100a (see FIG. 4) in which an immobilizing substance and a target substance are placed on a microarray substrate (i.e., pre-biochip) 101 that includes at least the substrate 10 and the partition 20 (i.e., does not include an immobilizing substance and a target substance), or a chip 100b (see FIG. 5) in which a carrier substance 53 is placed on the microarray substrate (i.e., pre-biochip) 101 that includes at least the substrate 10 and the partition 20 (i.e., does not include an immobilizing substance and a target substance). The microarray substrate (i.e., pre-biochip) 101 is a substrate (chip) that is used as a biochip or the like by introducing (placing) a target substance. The details of the biochip and the partition are described later.

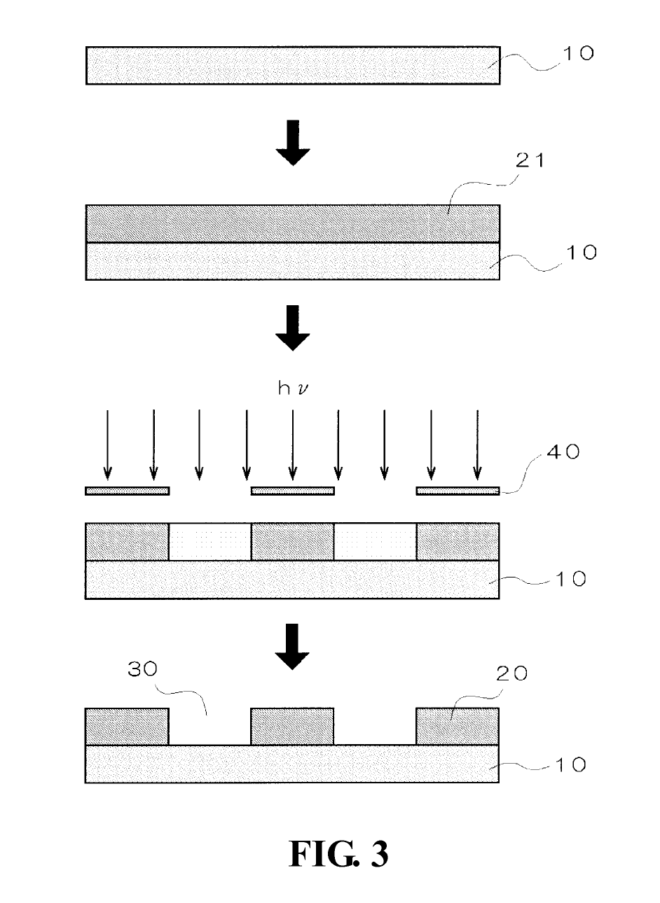

In the first film-forming step, a first film 21 is formed on the substrate 10 using the radiation-sensitive composition that includes at least one coloring agent (A) selected from the compound (a1) shown by the formula (1) and the violet pigment (a2) (see FIG. 3).

The cavities can be optically isolated while improving adhesion between the partition and the substrate (or another layer formed on the surface of the substrate) by utilizing the radiation-sensitive composition that includes at least one coloring agent (A) selected from the compound (a1) and the violet pigment (a2). Moreover, since the partition rarely swells when coming in contact with water or an aqueous liquid, removal of the partition from the surface of the substrate, or a decrease in adhesion between the partition and the substrate can be prevented.

The radiation-sensitive composition includes at least one coloring agent (A) selected from the compound (a1) and the violet pigment (a2). The details of the radiation-sensitive composition and at least one coloring agent (A) selected from the compound (a1) and the violet pigment (a2) are described later.

A film may be formed by an arbitrary method using the radiation-sensitive composition. A film is normally formed by applying the radiation-sensitive composition in a liquid state to a desired surface (e.g., the surface of the substrate or the surface of another layer formed on the substrate). The radiation-sensitive composition may be applied by an appropriate method (e.g., spin coating, cast coating, roll coating, or printing).

When the radiation-sensitive composition includes a solvent, a film obtained by applying the radiation-sensitive composition may optionally be prebaked (PB) to vaporize the solvent or the like included in the film. The prebaking conditions may be appropriately selected depending on the properties of the radiation-sensitive composition. For example, the heating temperature may be 30 to 240° C., and may preferably be 50 to 180° C. The heating time may be 30 to 1800 seconds, and may preferably be 60 to 600 seconds.

The thickness of the first film is not particularly limited, but may be 0.01 to 500 μm. The thickness of the first film is preferably 1 to 100 μm, and more preferably 10 to 70 μm. If the thickness of the first film is within the above range, the partition may have a height appropriate for a biochip.

The type of the substrate is not particularly limited. The substrate may be formed of an inorganic material, an organic material, or an inorganic-organic composite material. The upper (one) surface and the lower (other) surface of the substrate 10 may be formed of different materials. Examples of the material for the substrate include silicon, silicon dioxide, and inorganic materials including silicon as the main component, such as glass (including borosilicate glass, surface-modified glass, quartz glass, and the like). Further examples of the material for the substrate include organic materials such as polypropylene and polyacrylamide (including polyacrylamide that is surface-activated by acrylamide). A substrate that includes a reactive site (e.g., active amino group) that is suitable for improving adhesion between the substrate and the first film may also be used.

A substrate that includes a light-receiving element such as a solid-state imaging element (e.g., CMOS image sensor) may also be used as the substrate 10. When using a substrate that includes a light-receiving element, the substrate can receive fluorescence emitted due to the interaction or reaction between a probe molecule and a target molecule.

In the partition-forming step, the first film 21 is patterned by lithography to form the partition 20 (see FIG. 3).

The term “lithography” refers to a method that patterns the first film 21 by exposing the first film 21 via a pattern mask 40 having a desired pattern, and developing the first film 21. Specifically, the partition-forming step normally includes exposing the first film 21 via the pattern mask 40 (exposure step), and removing unnecessary area using a developer after the exposure step (development step).

FIG. 3 shows a case of using a negative-tone radiation-sensitive composition. The partition may also be formed by a similar method when using a positive-tone radiation-sensitive composition.

Examples of radiation used for exposure in the exposure step include a mercury spectrum (wavelength: 300 to 600 nm), light emitted from an LED lamp, and ultraviolet rays (including g-line, h-line, and i-line).

In the development step, an area that has become soluble in the developer due to the exposure step is removed. A known alkaline developer may be used as the developer.

The method of producing a microarray substrate according to one embodiment of the invention may include an additional step other than the first film-forming step and the partition-forming step. Examples of the additional step include a post-exposure bake (PEB). The apparent sensitivity of the first film can be improved by PEB. The PEB temperature may be appropriately selected depending on the components (composition) of the radiation-sensitive composition, the types of additives, and the like, but is preferably 30 to 200° C., and more preferably 50 to 150° C. The first film (partition) may be washed with water after the development step.

Further examples of the additional step include post-development bake. The post-development bake conditions may be appropriately selected depending on the components (composition) of the radiation-sensitive composition, the types of additives, and the like. The post-development bake temperature is normally 30 to 300° C., and preferably 50 to 250° C. The post-development bake time is normally 1 minute to 5 hours.

### [2] Radiation-Sensitive Composition

A radiation-sensitive composition according to one embodiment of the invention is used to form a partition of a microarray substrate that includes a substrate, a partition that is formed on a surface of the substrate, and an area that is positioned over the substrate and defined by the partition, the radiation-sensitive composition including (A) at least one coloring agent selected from the compound (a1) and the violet pigment (a2).

Specific examples of the compound (a1) include C.I. Pigment Red 254, C.I. Pigment Red 264, C.I. Pigment Red 255, C.I. Pigment Orange 71, C.I. Pigment Orange 73, and the like. Among these, C.I. Pigment Red 254, C.I. Pigment Red 264, and C.I. Pigment Red 255 are preferable from the viewpoint of preventing color mixture. These compounds (a1) may be used either individually or in combination.

The content of the compound (a1) is not particularly limited, but is preferably 0.01 to 300 parts by mass, more preferably 0.1 to 100 parts by mass, and still more preferably 1 to 100 parts by mass, based on 100 parts by mass of a polymer (B). If the content of the compound (a1) is within the above range, excellent adhesion and water resistance can be obtained.

Examples of the violet pigment (a2) include various types of C.I. Pigment Violet (Colour Index Generic Name).

Specific examples of the violet pigment (a2) include C.I. Pigment Violet 19, C.I. Pigment Violet 23, C.I. Pigment Violet 29, C.I. Pigment Violet 1, C.I. Pigment Violet 32, C.I. Pigment Violet 36, C.I. Pigment Violet 38, C.I. Pigment Violet 1:1, C.I. Pigment Violet 2, C.I. Pigment Violet 2:2, C.I. Pigment Violet 3, C.I. Pigment Violet 3:1, C.I. Pigment Violet 3:3, C.I. Pigment Violet 5, C.I. Pigment Violet 5:1, C.I. Pigment Violet 14, C.I. Pigment Violet 15, C.I. Pigment Violet 16, C.I. Pigment Violet 25, C.I. Pigment Violet 27, C.I. Pigment Violet 31, C.I. Pigment Violet 37, C.I. Pigment Violet 39, C.I. Pigment Violet 42, C.I. Pigment Violet 44, C.I. Pigment Violet 47, C.I. Pigment Violet 49, C.I. Pigment Violet 50, and the like. These pigments may be used either individually or in combination.

It is preferable that the violet pigment (a2) be at least one violet pigment selected from C.I. Pigment Violet 19, C.I. Pigment Violet 23, and C.I. Pigment Violet 29. These violet pigments achieve optical isolation at a content lower than that of other violet pigments. Moreover, these violet pigments exhibit excellent exposure sensitivity to a g-line, an h-line, and an i-line, and effectively improve adhesion between the partition and the substrate and the water resistance of the partition.

The radiation-sensitive composition according to one embodiment of the invention may include an additional pigment other than at least one coloring agent (A) selected from the compound (a1) and the violet pigment (a2). The type of additional pigment is not particularly limited. For example, a compound classified as a pigment in accordance with the Colour Index (C.I.) (published by the Society of Dyersand Colourists) (hereinafter may be referred to as “pigment compound”) may be used.

The radiation-sensitive composition according to one embodiment of the invention normally includes (B) a polymer. Various polymers may be used as the polymer (B) included in the radiation-sensitive composition depending on the type of the radiation-sensitive composition. Specifically, the radiation-sensitive composition according to one embodiment of the invention may be a negative-tone radiation-sensitive composition or a positive-tone radiation-sensitive composition. The polymer (B) may be an organic polymer (i.e., a polymer including a carbon skeleton), or an inorganic polymer (i.e., a polymer including a skeleton formed of an element (e.g., Si or Si and O) other than carbon). Specifically, the radiation-sensitive composition may be a negative-tone radiation-sensitive composition that includes an organic polymer as the polymer (B) (hereinafter may be referred to as “organic negative-tone composition”), a negative-tone radiation-sensitive composition that includes an inorganic polymer as the polymer (B) (hereinafter may be referred to as “inorganic negative-tone composition”), a positive-tone radiation-sensitive composition that includes an organic polymer as the polymer (B) (hereinafter may be referred to as “organic positive-tone composition”), or a positive-tone radiation-sensitive composition that includes an inorganic polymer as the polymer (B) (hereinafter may be referred to as “inorganic positive-tone composition”).

When the radiation-sensitive composition includes an organic polymer as the main component, the content of the organic polymer in the radiation-sensitive composition is 51 mass % or more (may be 100 mass %) based on the total amount (=100 mass %) of the radiation-sensitive composition. In this case, the radiation-sensitive composition does not include an inorganic polymer, or includes an inorganic polymer in an amount of less than 49 mass %. Likewise, when the radiation-sensitive composition includes an inorganic polymer as the main component, the content of the inorganic polymer in the radiation-sensitive composition is 51 mass % or more (may be 100 mass %) based on the total amount (=100 mass %) of the radiation-sensitive composition. In this case, the radiation-sensitive composition does not include an organic polymer, or includes an organic polymer in an amount of less than 49 mass %.

(1) Negative-Tone Radiation-Sensitive Composition that Includes Organic Polymer as Main Component

When using an organic negative-tone composition (1) as the radiation-sensitive composition, a composition disclosed in Japanese Patent Application Publication (KOKAI) No. 2007-293306, No. 2003-215802, No. 2004-10660, No. 2003-258422, No. 2004-10660, or No. 2004-171026, or the like may be used as the organic negative-tone composition.

Among these, it is preferable to use a composition disclosed in Japanese Patent Application Publication (KOKAI) No. 2007-293306. This composition includes an alkali-soluble organic polymer (B) as the polymer (B). It is preferable that the composition further include (C) a polyfunctional monomer and (D) a photoinitiator.

It is also preferable to use a polymer that includes a reactive group (e.g., ethylenically unsaturated linking group) (see Japanese Patent Application Publications (KOKAI) No. 2006-124664 and 2007-241247) as the polymer (B). The adhesion and the heat resistance of the partition can be improved when using a polymer that includes a reactive group.

When using the organic negative-tone composition (1) as the radiation-sensitive composition, the radiation-sensitive composition may include an additional component other than at least one coloring agent (A) selected from the compound (a1) and the violet pigment (a2) and the polymer (B). The radiation-sensitive composition may include the polyfunctional monomer (C) and the photoinitiator (D) as additional components.

The polyfunctional monomer (C) is preferably a polyfunctional compound that includes at least one ethylenically unsaturated group in the molecule and is liquid or solid at room temperature.

The photoinitiator (D) included in the radiation-sensitive composition refers to a compound that generates an active species that initiates polymerization of the polyfunctional monomer (C) upon exposure to light (e.g., light emitted from a semiconductor laser, a metal halide lamp, a high-pressure mercury lamp (e.g., g-line, h-line, or i-line), or an excimer laser, extreme ultraviolet rays, or electron beams).

Examples of the photoinitiator (D) include photoinitiators disclosed in Japanese Patent Application Publications (KOKAI) No. 2006-285035 and No. 2009-192613, and the like. Specific examples of the photoinitiator (D) include acyl phosphine oxide compounds, biimidazole compounds, benzoin compounds, acetophenone compounds, benzophenone compounds, α-diketone compounds, polynuclear quinone compounds, xanthone compounds, triazine compound, O-acyloxime compounds, and the like. These compounds may be used either individually or in combination. It is preferable to use acyl phosphine oxide compounds, biimidazole compounds, or O-acyloxime compounds as the photoinitiator (D) from the viewpoint of water-proof adhesion.

The radiation-sensitive composition (organic negative-tone composition (1)) may optionally include (E) an adhesion improver, (F) a surfactant, (G) an organic solvent, and the like.

The adhesion improver (E) further improves adhesion between the substrate and the partition. A functional silane coupling agent is preferably used as the adhesion improver (E).

Among the organic negative-tone composition (1), inorganic negative-tone composition (2), organic positive-tone composition (3), and inorganic positive-tone composition (4), the negative-tone radiation-sensitive composition (i.e., organic negative-tone composition (1) or inorganic negative-tone composition (2)) is preferable, and the organic negative-tone composition (1) is more preferable.

### [3] Partition of Microarray Substrate (Including Partition of Biochip)

A partition of a microarray substrate (including a partition of a biochip) according to one embodiment of the invention is produced using the above radiation-sensitive composition. Specifically, the partition according to one embodiment of the invention is obtained by forming the first film 21 on the substrate 10 using the radiation-sensitive composition that includes at least one coloring agent (A) selected from the compound (a1) and the violet pigment (a2), and patterning the first film 21 by lithography to form the partition 20 (see FIGS. 1 to 3).

The properties of the partition are not particularly limited, but the partition having a thickness of 35 μm may have a transmittance of light having a wavelength of 550 nm of 0 to 10%. When using the violet pigment, the partition having a thickness of 35 μm may have a transmittance of light having a wavelength of 500 to 600 nm of 0 to 40%. If the transmittance of the partition is within the above range, color mixture can be effectively prevented.

The shape of the partition is not particularly limited. It is preferable that the partition have a width (i.e., the distance between the cavities) of 1 μm or more. The width of the partition is more preferably 1 to 1000 μm, still more preferably 2 to 500 μm, and particularly preferably 5 to 50 μm.

### [4] Method of Producing Biochip (1)

A first method of producing a biochip according to one embodiment of the invention (see FIGS. 3 and 4) includes (a) a microarray substrate production step (i.e., a partition-forming step that forms a partition on a substrate), (b) an immobilizing substance placement step, and (c) an immobilization step.

In the microarray substrate production step (a) (see FIG. 3), the partition 20 is formed on the substrate 10 using the above method of producing a microarray substrate. The above method of producing a microarray substrate may be applied to the microarray substrate production step.

In the immobilizing substance placement step (b) (see FIG. 4), an immobilizing substance 51 for immobilizing a target substance 52 is placed in each area 30 (i.e., cavity) defined by the partition 20.

The immobilizing substance 51 refers to a substance that bonds (connects) the target substance and the substrate. Examples of the immobilizing substance include polylysine, collagen, laminin, a sialic acid-containing oligosaccharide, mannose-binding lectin, an integrin family ligand, a peptide, an antigen, an antibody, a nucleic acid, and the like. These immobilizing substances may be used either individually or in combination.

The immobilizing substance may be immobilized by an arbitrary method. The immobilizing substance may be immobilized using a chemical bond, physical adsorption, or the like.

The inner surface of the cavity 30 formed over the substrate 10 on which the partition 20 is formed (including the surface of the substrate and the surface of the partition) may be subjected to a surface treatment that facilitates placement of the immobilizing substance 51, a surface treatment that suppresses adhesion of the target substance, or the like before the immobilizing substance placement step (b). For example, the surface treatment may be implemented by preventing non-specific adhesion to a lipid membrane (cell membrane) using ethylenediamine or the like.

In the immobilization step (c) (see FIG. 4), the target substance 52 is immobilized on the immobilizing substance 51.

The target substance 52 refers to a substance that specifically binds to a target biopolymer or the like. Specific examples of the target substance 52 include a biological substance. Examples of the biological substance include eucaryotic cells, procaryotic cells, viruses, liposomes, and the like. Further examples of the biological substance include DNA, RNA, PNA, BNA, artificial nucleic acids, proteins (peptides), sugar chains, a combination (probe) thereof, and the like. These biological substances may be used either individually or in combination.

The target substance 52 may be immobilized by an arbitrary method. The target substance 52 may be immobilized using a chemical bond or physical adsorption.

### [5] Method of Producing Biochip (2)

A second method of producing a biochip according to one embodiment of the invention (see FIGS. 3 and 5) includes (a) a microarray substrate production step (i.e., a partition-forming step that forms a partition on a substrate), and (d) a carrier substance placement step.

In the microarray substrate production step (a) (see FIG. 3), the partition 20 is formed on the substrate 10 using the above method of producing a microarray substrate. The above method of producing a microarray substrate may be applied to the microarray substrate production step.

In the carrier substance placement step (d) (see FIG. 5), a carrier substance 53 that carries a target substance 52 on the surface of a solid-phase carrier 54 is placed in each cavity 30 formed over the substrate 10 on which the partition 20 is formed.

The solid-phase carrier 54 refers to a solid-phase substance that carries the target substance 52 on its surface. The solid-phase carrier 54 is normally a particle. The type of particle is not particularly limited. The particle may be an organic particle or an inorganic particle (preferably an inorganic particle). It is more preferable to use a particle formed of a metal and/or a metal oxide. For example, a magnetic particle may be used as the particle formed of a metal and/or a metal oxide. The magnetic particle has magnetism. When using the magnetic particle, the target substance 52 can be easily isolated from the solid-phase carrier 54 by utilizing an external magnetic field.

Examples of the material for the magnetic particle include a salt, an oxide, a boride, or a sulfide of iron, cobalt, or nickel, a rare-earth metal compound that has high magnetic susceptibility (e.g., hematite or ferrite), and the like. These materials may be used either individually or in combination.

Specific examples of the magnetic particle include magnetite and ferromagnetic alloys such as an iron-lead alloy, an iron-platinum alloy, and a cobalt-platinum alloy. These magnetic particles may be used either individually or in combination.

When the solid-phase carrier 54 is a particle, the particle size of the solid-phase carrier 54 is not particularly limited. A nanoparticle, a microparticle, a milliparticle, or the like may be appropriately used.

An immobilizing substance for immobilizing the target substance 52 may be provided on the surface of the solid-phase carrier 54. The details of the immobilizing substance 51 described in connection with the step (b) of the first method of producing a biochip may be applied to the immobilizing substance.

The details of the target substance 52 described in connection with the step (c) of the first method of producing a biochip may be applied to the target substance 52.

The carrier substance 53 that carries the target substance 52 on the surface of the solid-phase carrier 54 may be placed in each cavity 30 (formed over the substrate 10 on which the partition 20 is formed) by an arbitrary method. The carrier substance 53 is normally placed in each cavity 30 by applying a dispersion that contains the carrier substance 53 to the substrate 10 on which the partition 20 is formed.

In the step (d), a substance (e.g., nanoparticle) smaller than the carrier substance may be placed in each cavity so that the carrier substance is not removed from the cavity of the microarray substrate. A substance that causes the biochip to efficiently function (i.e., a substance that has a catalytic function or an enzymatic function for promoting a reaction (hybridization) between the target substance and a sample (e.g., DNA or RNA) may be placed in each cavity.

### [6] Biochip

A biochip according to one embodiment of the invention is obtained by the method of producing a biochip according to one embodiment of the invention. The microarray substrate (i.e., pre-biochip) 101 shown in FIGS. 1 and 2 includes at least the substrate 10 and the partition 20. The microarray substrate 101 includes the areas 30 that are positioned over the substrate 10 and defined by the partition 20. Each area 30 is surrounded by the partition 20, and functions as a depression (i.e., cavity 30). A plurality of cavities 30 are normally provided in one microarray substrate (i.e., pre-biochip) 101. The cavity 30 may be used as a well. As shown in FIG. 4, the biochip includes the immobilizing substance 51 that is placed on at least the surface of the substrate inside the cavity 30, and the target substance 52 immobilized on the immobilizing substance 51. Alternatively, the biochip includes the carrier substance 53 that is placed in the cavity 30 and carries the target substance 52 on the surface of the solid-phase carrier 54, as shown in FIG. 5.

The open shape of the cavity is not particularly limited. The open shape of the cavity may be a quadrangle, a circle, a triangle, a polygon other than a quadrangle and a triangle, or another shape.

The shape of the bottom of the cavity may be the same as the open shape, or may be narrower than the open shape. The bottom of the cavity may have another shape.

The cavity may be formed through the partition (i.e., the bottom of the cavity may be the surface of a layer (substrate or another layer)) under the partition, or may not be formed through the partition (i.e., the bottom of the cavity may be formed by the partition).

The biochip according to one embodiment of the invention may be utilized as a biochip that detects fluorescence (e.g., DNA sequencing biochip or diagnostic biochip).

### EXAMPLES

The embodiments of the invention are further described below by way of examples. Note that the invention is not limited to the following examples. In the following examples, the units “parts” and “%” respectively refer to “parts by mass” and “mass %” unless otherwise indicated.

### [1] Preparation of Dispersion of Coloring Agent (A)

### Preparation Example 1

### Dispersion (A1)

10 parts by mass of C.I. Pigment Red 254 (compound (a1)), 3 parts by mass (solid content) of Disperbyk-2001 (manufactured by BYK Japan KK) (dispersant), and propylene glycol monomethyl ether acetate (solvent) were mixed for 12 hours using a bead mill to obtain a dispersion (A1) (solid content: 20 mass %) in which C.I. Pigment Red 254 was dispersed.

### Preparation Example 2

### Dispersion (A2)

A dispersion (A2) (solid content: 20 mass %) in which C.I. Pigment Red 264 was dispersed was obtained in the same manner as in Preparation Example 1, except for using C.I. Pigment Red 264 (compound (al)) instead of C.I. Pigment Red 254.

### Preparation Example 3

### Dispersion (A3)

A dispersion (A3) (solid content: 20 mass %) in which C.I. Pigment Red 277 was dispersed was obtained in the same manner as in Preparation Example 1, except for using C.I. Pigment Red 277 (compound other than the compound (a1)) instead of C.I. Pigment Red 254.

### Preparation Example 4

### Dispersion (A4)

10 parts by mass of C.I. Pigment Red 123 (compound other than the compound (a1)), 3 parts by mass (solid content) of Disperbyk-2001 (manufactured by BYK Japan KK) (dispersant), and propylene glycol monomethyl ether acetate (solvent) were mixed for 12 hours using a bead mill to obtain a dispersion (A4) (solid content: 20 mass %) in which C.I. Pigment Red 123 was dispersed.

### Preparation Example 5

### Dispersion (A5)

2 parts by mass of C.I. Pigment Violet 19 (violet pigment (a2)), 1 part by mass (solid content) of Disperbyk-2001 (manufactured by BYK Japan KK) (dispersant), and propylene glycol monomethyl ether acetate (solvent) were mixed for 12 hours using a bead mill to obtain a dispersion (A5) (solid content: 20 mass %) in which C.I. Pigment Violet 19 was dispersed.

### Preparation Example 6

### Dispersion (A6)

4 parts by mass of C.I. Pigment Violet 29 (violet pigment (a2)), 1 part by mass (solid content) of Disperbyk-2001 (manufactured by BYK Japan KK) (dispersant), and propylene glycol monomethyl ether acetate (solvent) were mixed for 12 hours using a bead mill to obtain a dispersion (A6) (solid content: 20 mass %) in which C.I. Pigment Violet 29 was dispersed.

### Preparation Example 7

### Dispersion (A7)

4 parts by mass of C.I. Pigment Violet 23 (violet pigment (a2)), 1 part by mass (solid content) of Disperbyk-2001 (manufactured by BYK Japan KK) (dispersant), and propylene glycol monomethyl ether acetate (solvent) were mixed for 12 hours using a bead mill to obtain a dispersion (A7) (solid content: 20 mass %) in which C.I. Pigment Violet 23 was dispersed.

### Preparation Example 8

### Dispersion (A8)

4 parts by mass of C.I. Pigment Blue 15:6 (compound other than the violet pigment (a2)), 5 parts by mass of C.I. Pigment Red 123 (compound other than the violet pigment (a2)), 1 part by mass (solid content) of Disperbyk-2001 (manufactured by BYK Japan KK) (dispersant), and propylene glycol monomethyl ether acetate (solvent) were mixed for 12 hours using a bead mill to obtain a dispersion (A8) (solid content: 20 mass %) in which C.I. Pigment Blue 15:6 and C.I. Pigment Red 123 were dispersed.

### [2] Synthesis of Polymer (B)

### Synthesis Example 1

### Synthesis of Polymer (B1)

A flask equipped with a cooling tube and a stirrer was charged with 3 parts by mass of 2,2′-azobisisobutyronitrile and 200 parts by mass of propylene glycol monomethyl ether acetate. After the addition of 10 parts by mass of methacrylic acid, 25 parts by mass of tricyclo[5.2.1.0^{2.6}]decanyl methacrylate, 20 parts by mass of isoboronyl acrylate, 30 parts by mass of n-butyl acrylate, 15 parts by mass of p-isopropenylphenol (monomers), and 5 parts by mass of 1-methyl-4-isopropylidene-1-cyclohexene (molecular-weight modifier), the atmosphere inside the flask was replaced with nitrogen. The temperature of the reaction solution was increased to 80° C. while slowly stirring the reaction solution, and the monomers were polymerized at 80° C. for 5 hours to obtain a solution of a polymer (B1) (Mw: 10,000, Mn: 6000, solid content: 31.2 mass %).

### Synthesis Example 2

### Synthesis of Polymer (B2)

A solution of a polymer (B2) was obtained in the same manner as in Synthesis Example 1, except for changing the amounts of tricyclo[5.2.1.0^{2.6}]decanyl methacrylate, isoboronyl acrylate, and n-butyl acrylate as shown in Table 1, and using benzyl methacrylate instead of p-isopropenylphenol (Mw: 10,000, Mn: 4000, solid content: 30 mass %).

### Synthesis Example 3

### Synthesis of Polymer (B3)

A solution of a polymer (B3) was obtained in the same manner as in Synthesis Example 1, except for changing the amounts of methacrylic acid and tricyclo[5.2.1.0^{2.6}]decanyl methacrylate as shown in Table 1, and using benzyl methacrylate instead of p-isopropenylphenol (Mw: 10,000, Mn: 4000, solid content: 30 mass %).

Note that the polymer (B3) was used as a raw material for polymers (B6) and (B7).

### Synthesis Example 4

### Synthesis of Polymer (B4)

A solution of a polymer (B4) was obtained in the same manner as in Synthesis Example 3, except for changing the amounts of methacrylic acid and n-butyl acrylate as shown in Table 1, and further adding 15 parts by mass of hydroxyethyl acrylate (Mw: 10,000, Mn: 4000, solid content: 30 mass %).

Note that the polymer (B4) was used as a raw material for a polymer (B8).

### Synthesis Example 5

### Synthesis of Polymer (B5)

A solution of a polymer (B5) was obtained in the same manner as in Synthesis Example 1, except for changing the amounts of methacrylic acid, tricyclo[5.2.1.0^{2.6}]decanyl methacrylate, and isobornyl acrylate as shown in Table 1, and using phenoxy diethylene glycol acrylate instead of n-butyl acrylate (Mw: 9000, Mn: 4500, solid content: 30 mass %).

### Synthesis Example 6

### Synthesis of Polymer (B6)

15 parts by mass of glycidyl methacrylate (end-modifying component), 1.4 parts by mass of tetrabutylammonium bromide, and 0.05 parts by mass of 4-methylphenol were added to 100 parts by mass of the polymer (B3) obtained in Synthesis Example 3. The mixture was reacted (to react the end carboxyl group and the epoxy group) at 80° C. for 10 hours to obtain a solution of a polymer (B6) including a polymerizable group (Mw: 11,000, Mn: 4500, solid content: 30 mass %).

### Synthesis Example 7

### Synthesis of Polymer (B7)

15 parts by mass of 4-hydroxybutyl acrylate glycidyl ether (end-modifying component), 1.4 parts by mass of tetrabutylammonium bromide, and 0.05 parts by mass of 4-methylphenol were added to 100 parts by mass of the polymer (B3) obtained in Synthesis Example 3. The mixture was reacted (to react the end carboxyl group and the epoxy group) at 80° C. for 10 hours to obtain a solution of a polymer (B7) including a polymerizable group (Mw: 11,000, Mn: 4500, solid content: 30 mass %).

### Synthesis Example 8

### Synthesis of Polymer (B8)

18 parts by mass of 2-methacryloyloxyethyl isocyanate (end-modifying component) (“Karenz MOI” manufactured by Showa Denko K.K.), 0.3 parts by mass of dibutyltin laurate, and 0.1 parts by mass of 4-methylphenol were added to 100 parts by mass of the polymer (B4) obtained in Synthesis Example 4. The mixture was stirred at 40° C. for 1 hour, and then stirred at 60° C. for 2 hours (to react the end carboxyl group and the isocyanate group) to obtain a solution of a polymer (B8) including a polymerizable group (Mw: 11,000, Mn: 4500, solid content: 35.0 mass %).

In Synthesis Example 8, the reaction was checked by the infrared radiation (IR) absorption spectrum. It was confirmed that the peak at around 2270 cm⁻¹ attributed to the isocyanate group of 2-methacryloyloxyethyl isocyanate decreased with time.

TABLE 1

| | | Polymer (B) | | | | | | | |
|---|---|---|---|---|---|---|---|---|---|
| | | B1 | B2 | B3 | B4 | B5 | B6 | B7 | B8 |
| Monomer/ | Methacrylic acid | 10 | 10 | 20 | 15 | 11 | Polymer | Polymer | Polymer |
| polymer | Tricyclo[5.2.1.0^{2.6}]decanyl | 25 | 35 | 15 | 15 | 15 | (B3) | (B3) | (B4) |
| | methacrylate | | | | | | 100 | 100 | 100 |
| | Isobornyl acrylate | 20 | 15 | 20 | 20 | 39 | | | |
| | n-Butyl acrylate | 30 | 25 | 30 | 20 | — | | | |
| | p-Isopropenylphenol | 15 | — | — | — | 15 | | | |
| | Benzyl methacrylate | — | 15 | 15 | 15 | — | | | |
| | Hydroxyethyl acrylate | — | — | — | 15 | — | | | |
| | Phenoxy diethylene glycol acrylate | — | — | — | — | 20 | | | |

| | | | | | |
|---|---|---|---|---|---|
| End-modifying | Glycidyl methacrylate | — | 15 | — | — |
| component | 4-Hydroxybutyl acrylate glycidyl | — | — | 15 | — |
| | ether | | | | |
| | 2-Methacryloyloxyethyl isocyanate | — | — | — | 18 |

| | | | | | | | | |
|---|---|---|---|---|---|---|---|---|
| Weight average molecular weight (Mw) | 10000 | 10000 | 10000 | 10000 | 9000 | 11000 | 11000 | 11000 |
| Number average molecular weight (Mw) | 6000 | 4000 | 4000 | 4000 | 4500 | 4500 | 4500 | 4500 |

### [3] Preparation of Radiation-Sensitive Composition

### Example 1

60 parts by mass of the coloring agent dispersion (A1) obtained in Preparation Example 1, 100 parts by mass of the polymer (B1) obtained in Synthesis Example 1, 60 parts by mass of a polyfunctional monomer (C1), 19 parts by mass of a photoinitiator (D1), 4 parts by mass of a photoinitiator (D2), 3 parts by mass of an adhesion improver (E1), 0.1 parts by mass of a surfactant (F1), and an organic solvent (G1) were mixed to obtain a radiation-sensitive composition (solid content: 50 mass %) (Example 1).

Polyfunctional monomer (C1): dipentaerythritol hexaacrylate (“Kayarad DPHA” manufactured by Nippon Kayaku Co., Ltd.)
Photoinitiator (D1): 2,2-dimethoxy-1,2-diphenylethan-1-one (“Irgacure 651” manufactured by Ciba Specialty Chemicals)
Photoinitiator (D2): “Lucirin LR 8953X” manufactured by BASF
Adhesion improver (E1) (silane coupling agent): tris(3-trimethoxysilylpropyl)isocyanurate (“Y-11597” manufactured by Momentive Performance Materials Inc.)
Surfactant (F1): fluorine-based surfactant (“FTX-218” manufactured by NEOS Co., Ltd.)
Organic solvent (G1): propylene glycol monomethyl ether acetate

### Example 2

A radiation-sensitive composition (solid content: 60 mass %) (Example 2) was obtained in the same manner as in Example 1, except for using the coloring agent dispersion (A2) instead of the coloring agent dispersion (A1).

### Example 3

A radiation-sensitive composition (solid content: 50 mass %) (Example 3) was obtained in the same manner as in Example 1, except that 50 parts by mass of a polyfunctional monomer (C2) (“Aronix M-450” manufactured by Toagosei Co., Ltd.) was used instead of 60 parts by mass of the polyfunctional monomer (C1), 2 parts by mass of a photoinitiator (D3) (“Irgacure OXE01” manufactured by Ciba Specialty Chemicals) was used instead of 19 parts by mass of the photoinitiator (D1) and 4 parts by mass of the photoinitiator (D2), and the adhesion improver (E1) was not used.

### Example 4

A radiation-sensitive composition (solid content: 50 mass %) (Example 4) was obtained in the same manner as in Example 4, except for using the polymer (B2) instead of the polymer (B1).

### Example 5

A radiation-sensitive composition (solid content: 50 mass %) (Example 5) was obtained in the same manner as in Example 4, except for using a photoinitiator (D4) (“Irgacure OXE02” manufactured by Ciba Specialty Chemicals) instead of the photoinitiator (D3).

### Example 6

60 parts by mass of the coloring agent dispersion (A1) obtained in Preparation Example 1, 100 parts by mass of the polymer (B6) obtained in Synthesis Example 6, 50 parts by mass of the polyfunctional monomer (C2), 20 parts by mass of the photoinitiator (D1), 20 parts by mass of the photoinitiator (D2), 0.1 parts by mass of the surfactant (F1), and the organic solvent (G1) were mixed to obtain a radiation-sensitive composition (solid content: 50 mass %) (Example 6).

### Example 7

60 parts by mass of the coloring agent dispersion (A1) obtained in Preparation Example 1, 100 parts by mass of the polymer (B7) obtained in Synthesis Example 7, 50 parts by mass of the polyfunctional monomer (C2), 10 parts by mass of a photoinitiator (D5) (“Irgacure 819” manufactured by Ciba Specialty Chemicals), 0.1 parts by mass of the surfactant (F1), and the organic solvent (G1) were mixed to obtain a radiation-sensitive composition (solid content: 50 mass %) (Example 7).

### Example 8

A radiation-sensitive composition (solid content: 50 mass %) (Example 8) was obtained in the same manner as in Example 7, except for using the polymer (B8) obtained in Synthesis Example 8 instead of the polymer (B7).

### Comparative Example 1

A radiation-sensitive composition (solid content: 60 mass %) (Comparative Example 1) was obtained in the same manner as in Example 1, except for using 95 parts by mass of the dispersion (A3) instead of the coloring agent dispersion (A1).

### Comparative Example 2

A radiation-sensitive composition (solid content: 60 mass %) (Comparative Example 2) was obtained in the same manner as in Example 1, except for using 35 parts by mass of the dispersion (A4) instead of the coloring agent dispersion (A1).

TABLE 2

| | | Dispersion of coloring | | | | | | | | | | | | | | | | | |
|---|---|---|---|---|---|---|---|---|---|---|---|---|---|---|---|---|---|---|---|
| | | agent (A) | | | | | | | | | | | | | | | | Adhesion | |
| | | Compound | | Comparison | | | | | | | Polyfunctional | | | | | | | improver | Surfactant |
| | | (a1) | | coloring agent | | Polymer (B) | | | | | monomer (C) | | Photoinitiator (D) | | | | | (E) | (F) |
| | | A1 | A2 | A3 | A4 | B1 | B2 | B6 | B7 | B8 | C1 | C2 | D1 | D2 | D3 | D4 | D5 | E1 | F1 |
| Example | 1 | 60 | — | — | — | 100 | — | — | — | — | 60 | — | 19 | 4 | — | — | — | 3 | 0.1 |
| | 2 | — | 60 | — | — | 100 | — | — | — | — | 60 | — | 19 | 4 | — | — | — | 3 | 0.1 |
| | 3 | 60 | — | — | — | 100 | — | — | — | — | — | 50 | — | — | 2 | — | — | — | 0.1 |
| | 4 | 60 | — | — | — | — | 100 | — | — | — | — | 50 | — | — | 2 | — | — | — | 0.1 |
| | 5 | 60 | — | — | — | — | 100 | — | — | — | — | 50 | — | — | — | 2 | — | — | 0.1 |
| | 6 | 60 | — | — | — | — | — | 100 | — | — | — | 50 | 20 | 20 | — | — | — | — | 0.1 |
| | 7 | 60 | — | — | — | — | — | — | 100 | — | — | 50 | — | — | — | — | 10 | — | 0.1 |
| | 8 | 60 | — | — | — | — | — | — | — | 100 | — | 50 | — | — | — | — | 10 | — | 0.1 |
| Compar- | 1 | — | — | 95 | — | — | — | — | — | — | 60 | — | 19 | 4 | — | — | — | 3 | 0.1 |
| ative | 2 | — | — | — | 35 | — | — | — | — | — | 60 | — | 19 | 4 | — | — | — | 3 | 0.1 |
| Example | | | | | | | | | | | | | | | | | | | |

The components shown in Table 2 are as follows.

Polyfunctional monomer (C1): dipentaerythritol hexaacrylate (“Kayarad DPHA” manufactured by Nippon Kayaku Co., Ltd.)
Polyfunctional monomer (C2): “Aronix M-450” manufactured by Toagosei Co., Ltd.
Photoinitiator (D1): 2,2-dimethoxy-1,2-diphenylethan-1-one (“Irgacure 651” manufactured by Ciba Specialty Chemicals)
Photoinitiator (D2): “Lucirin LR 8953X” manufactured by BASF
Photoinitiator (D3): “Irgacure OXE01” manufactured by Ciba Specialty Chemicals
Photoinitiator (D4): “Irgacure OXE02” manufactured by Ciba Specialty Chemicals
Photoinitiator (D5): “Irgacure 819” manufactured by Ciba Specialty Chemicals
Adhesion improver (E1) (silane coupling agent): tris(3-trimethoxysilylpropyl)isocyanurate (“Y-11597” manufactured by Momentive Performance Materials Inc.)
Surfactant (F1): fluorine-based surfactant (“FTX-218” manufactured by NEOS Co., Ltd.)

### Example 9

38 parts by mass of the coloring agent dispersion (A5) obtained in Preparation Example 5, 100 parts by mass of the polymer (B1) obtained in Synthesis Example 1, 30 parts by mass of the polyfunctional monomer (C1), 30 parts by mass of a polyfunctional monomer (C3) (pentaerythritol tetraacrylate), 20 parts by mass of the photoinitiator (D1), 20 parts by mass of the photoinitiator (D2), 3 parts by mass of the adhesion improver (E1), 0.1 parts by mass of the surfactant (F1), and the organic solvent (G1) were mixed to obtain a radiation-sensitive composition (solid content: 50 mass %) (Example 9).

### Example 10

31 parts by mass of the coloring agent dispersion (A6) obtained in Preparation Example 6, 100 parts by mass of the polymer (B5) obtained in Synthesis Example 5, 60 parts by mass of the polyfunctional monomer (C1), 20 parts by mass of the photoinitiator (D1), 4 parts by mass of a photoinitiator (D2), 3 parts by mass of the adhesion improver (E1), 0.1 parts by mass of the surfactant (F1), and the organic solvent (G1) were mixed to obtain a radiation-sensitive composition (solid content: 50 mass %) (Example 10).

### Example 11

31 parts by mass of the coloring agent dispersion (A7) obtained in Preparation Example 7, 100 parts by mass of the polymer (B1) obtained in Synthesis Example 1, 60 parts by mass of the polyfunctional monomer (C1), 20 parts by mass of the photoinitiator (D1), 4 parts by mass of a photoinitiator (D2), 3 parts by mass of the adhesion improver (E1), 0.1 parts by mass of the surfactant (F1), and the organic solvent (G1) were mixed to obtain a radiation-sensitive composition (solid content: 50 mass %) (Example 11).

### Example 12

30 parts by mass of the coloring agent dispersion (A7), 100 parts by mass of the polymer (B5), 50 parts by mass of the polyfunctional monomer (C2), 2 parts by mass of the photoinitiator (D3), 0.1 parts by mass of the surfactant (F1), and the organic solvent (G1) were mixed to obtain a radiation-sensitive composition (solid content: 50 mass %) (Example 12).

### Example 13

30 parts by mass of the coloring agent dispersion (A7), 100 parts by mass of the polymer (B2), 50 parts by mass of the polyfunctional monomer (C2), 2 parts by mass of the photoinitiator (D3), 0.1 parts by mass of the surfactant (F1), and the organic solvent (G1) were mixed to obtain a radiation-sensitive composition (solid content: 50 mass %) (Example 13).

### Example 14

30 parts by mass of the coloring agent dispersion (A7), 100 parts by mass of the polymer (B2), 50 parts by mass of the polyfunctional monomer (C2), 2 parts by mass of the photoinitiator (D4), 0.1 parts by mass of the surfactant (F1), and the organic solvent (G1) were mixed to obtain a radiation-sensitive composition (solid content: 50 mass %) (Example 14).

### Example 15

25 parts by mass of the coloring agent dispersion (A7), 100 parts by mass of the polymer (B6), 50 parts by mass of the polyfunctional monomer (C2), 20 parts by mass of the photoinitiator (D1), 20 parts by mass of the photoinitiator (D2), 0.1 parts by mass of the surfactant (F1), and the organic solvent (G1) were mixed to obtain a radiation-sensitive composition (solid content: 50 mass %) (Example 15).

### Example 16

30 parts by mass of the coloring agent dispersion (A7), 100 parts by mass of the polymer (B7), 50 parts by mass of the polyfunctional monomer (C2), 2 parts by mass of the photoinitiator (D5), 0.1 parts by mass of the surfactant (F1), and the organic solvent (G1) were mixed to obtain a radiation-sensitive composition (solid content: 50 mass %) (Example 16).

### Example 17

30 parts by mass of the coloring agent dispersion (A7), 100 parts by mass of the polymer (B8), 50 parts by mass of the polyfunctional monomer (C2), 2 parts by mass of the photoinitiator (D5), 0.1 parts by mass of the surfactant (F1), and the organic solvent (G1) were mixed to obtain a radiation-sensitive composition (solid content: 50 mass %) (Example 17).

### Comparative Example 3

A radiation-sensitive composition (solid content: 50 mass %) (Comparative Example 3) was obtained in the same manner as in Example 10, except for using 56 parts by mass of the coloring agent dispersion (A8) obtained in Preparation Example 8 instead of the coloring agent dispersion (A6), and using the polymer (B1) instead of the polymer (B5).

TABLE 3-1

| | | Dispersion of coloring agent (A) | | | | | | | | | | | | |
|---|---|---|---|---|---|---|---|---|---|---|---|---|---|---|
| | | Violet | | Comparison | | | | | | | | Polyfunctional | | |
| | | pigment (a2) | | coloring agent | | Polymer (B) | | | | | | monomer (C) | | |
| | | A5 | A6 | A7 | A8 | B1 | B2 | B5 | B6 | B7 | B8 | C1 | C2 | C3 |
| Example | 9 | 38 | — | — | — | 100 | — | — | — | — | — | 30 | — | 30 |
| | 10 | — | 31 | — | — | — | — | 100 | — | — | — | 60 | — | — |
| | 11 | — | — | 31 | — | 100 | — | — | — | — | — | — | — | 60 |
| | 12 | — | — | 30 | — | — | — | 100 | — | — | — | — | 50 | — |
| | 13 | — | — | 30 | — | — | 100 | — | — | — | — | — | 50 | — |
| | 14 | — | — | 30 | — | — | 100 | — | — | — | — | — | 50 | — |
| | 15 | — | — | 25 | — | — | — | — | 100 | — | — | — | 50 | — |
| | 16 | — | — | 30 | — | — | — | — | — | 100 | — | — | 50 | — |
| | 17 | — | — | 30 | — | — | — | — | — | — | 100 | — | 50 | — |
| Comparative | 3 | — | — | — | 56 | 100 | — | — | — | — | — | 60 | — | — |
| Example | | | | | | | | | | | | | | |

TABLE 3-2

| | | | | | | | Adhesion | Surfactant |
|---|---|---|---|---|---|---|---|---|
| | | Photoinitiator (D) | | | | | improver (E) | (F) |
| | | D1 | D2 | D3 | D4 | D5 | E1 | F1 |
| Example | 9 | 20 | 20 | — | — | — | 3 | 0.1 |
| | 10 | 20 | 20 | — | — | — | 3 | 0.1 |
| | 11 | 20 | 20 | — | — | — | 3 | 0.1 |
| | 12 | — | — | 2 | — | — | — | 0.1 |
| | 13 | — | — | 2 | — | — | — | 0.1 |
| | 14 | — | — | — | 2 | — | — | 0.1 |
| | 15 | 20 | 20 | — | — | — | — | 0.1 |
| | 16 | — | — | — | — | 10 | — | 0.1 |
| | 17 | — | — | — | — | 10 | — | 0.1 |
| Comparative | 3 | 20 | 20 | — | — | — | 3 | 0.1 |
| Example | | | | | | | | |

The components shown in Tables 3-1 and 3-2 are as follows.

Polyfunctional monomer (C1): dipentaerythritol hexaacrylate (“Kayarad DPHA” manufactured by Nippon Kayaku Co., Ltd.)
Polyfunctional monomer (C2): “Aronix M-450” manufactured by Toagosei Co., Ltd.
Polyfunctional monomer (C3): pentaerythritol tetracrylate
Photoinitiator (D1): 2,2-dimethoxy-1,2-diphenylethan-1-one (“Irgacure 651” manufactured by Ciba Specialty Chemicals)
Photoinitiator (D2): “Lucirin LR 8953X” manufactured by BASF
Photoinitiator (D3): “Irgacure OXE01” manufactured by Ciba Specialty Chemicals
Photoinitiator (D4): “Irgacure OXE02” manufactured by Ciba Specialty Chemicals
Photoinitiator (D5): “Irgacure 819” manufactured by Ciba Specialty Chemicals
Adhesion improver (E1) (silane coupling agent): tris(3-trimethoxysilylpropyl)isocyanurate (“Y-11597” manufactured by Momentive Performance Materials Inc.)
Surfactant (F1): fluorine-based surfactant (“FTX-218” manufactured by NEOS Co., Ltd.)

### [4] Evaluation

### (1) Measurement of Light Transmittance (Wavelength: 550 nm)

The radiation-sensitive composition (Examples 1 to 17 and Comparative Examples 1 to 3) was spin-coated onto a silicon wafer. The radiation-sensitive composition was heated at 110° C. for 5 minutes on a hot plate to obtain a first film having a thickness of 35 μm. The light transmittance (wavelength: 550 nm) of the first film (partition) thus obtained was measured using a spectrophotometer (“2010 U” manufactured by Hitachi, Ltd.). The results are shown in Table 4.

### (2) Measurement of Light Transmittance (Wavelength: 500 to 600 nm)

The radiation-sensitive composition (Examples 9 to 17 and Comparative Example 3) was spin-coated onto a silicon wafer. The radiation-sensitive composition was heated at 110° C. for 5 minutes on a hot plate to obtain a first film having a thickness of 35 μm. The light transmittance (wavelength: 500 to 600 nm) of the first film (partition) thus obtained was measured using a spectrophotometer (“2010 U” manufactured by Hitachi, Ltd.). The results are shown in Table 4.

### (3) Evaluation of Adhesion Between Partition and Substrate

The radiation-sensitive composition (Examples 1 to 17 and Comparative Examples 1 to 3) was spin-coated onto a silicon wafer. The radiation-sensitive composition was heated at 110° C. for 5 minutes on a hot plate to obtain a first film having a thickness of 45 μm.

Ultraviolet rays were applied to the first film via a mask at a dose of 300 to 1000 mJ/cm² using an ultra-high-pressure mercury lamp (“HBO” manufactured by OSRAM, output: 1000 W). The dose was checked using an illuminometer (“UV-M10” manufactured by ORC Co., Ltd., probe (photodetector): “UV-M10”).

The first film was then developed at room temperature using a 2.38 wt % tetramethylammonium hydroxide aqueous solution, washed with water, and blown with nitrogen. The first film was then heated at 220° C. for 1 hour using an oven to obtain a pattern (partition) having ten square (25×25 μm) depressions (cavities) at a pitch of 30 μm (thickness (height) of partition: 35 μm).

The partition was observed using a scanning electron microscope (“S-4200” manufactured by Hitachi, Ltd.) (magnification: 1000), and adhesion between the partition and the substrate was evaluated in accordance with the following standard. The results are shown in Table 4.

A: Removal of the partition from the substrate was not observed in each cavity.
B: Removal of the partition from the substrate was observed in one or more cavities.

### (4) Evaluation of Water Resistance of Partition

The partition (partition formed on the substrate) subjected to “(3) Evaluation of adhesion between partition and substrate” was immersed in water, and kept at 55° C. for 24 hours. Water was then blown off with nitrogen. The partition was observed using a scanning electron microscope (“S-4200” manufactured by Hitachi, Ltd.) (magnification: 1000), and adhesion between the partition and the substrate was evaluated in accordance with the following standard. The results are shown in Table 4.

A: Removal of the partition from the substrate was not observed in each cavity.
B: Removal of the partition from the substrate was observed in one or more cavities.

### (5) Evaluation of Sensitivity

A dose required to form the partition in “(3) Evaluation of adhesion between partition and substrate” was taken as the sensitivity (mJ/cm²). The results are shown in Table 4.

### (6) Shape of Well

The shape of each cavity (well) formed in “(3) Evaluation of adhesion between partition and substrate” was observed using a scanning electron microscope (“S-4200” manufactured by Hitachi, Ltd.), and evaluated in accordance with the following standard.

A: All of the cavities had a 25×25 μm square shape.
B: One or more cavities did not have a 25×25 μm square shape.

TABLE 4

| | | Light | Light | | | | |
|---|---|---|---|---|---|---|---|
| | | transmittance | transmittance | | Water | Shape | Sensitivity |
| | | (550 nm) | (500-600 nm) | Adhesion | resistance | of well | (mJ/cm²) |
| Example | 1 | 6% T | — | A | A | A | — |
| | 2 | 6% T | — | A | A | A | — |
| | 3 | <10% T | — | A | A | A | — |
| | 4 | <10% T | — | A | A | A | — |
| | 5 | <10% T | — | A | A | A | — |
| | 6 | <10% T | — | A | A | A | — |
| | 7 | <10% T | — | A | A | A | — |
| | 8 | <10% T | — | A | A | A | — |
| | 9 | <10% T | <40% T | A | A | A | 500 |
| | 10 | <10% T | <40% T | A | A | A | 500 |
| | 11 | <10% T | <40% T | A | A | A | 500 |
| | 12 | <10% T | <40% T | A | A | A | 350 |
| | 13 | <10% T | <40% T | A | A | A | 350 |
| | 14 | <10% T | <40% T | A | A | A | 350 |
| | 15 | <10% T | <40% T | A | A | A | 400 |
| | 16 | <10% T | <40% T | A | A | A | 200 |
| | 17 | <10% T | <40% T | A | A | A | 200 |
| Comparative | 1 | 6% T | — | B | B | A | — |
| Example | 2 | 6% T | — | B | B | A | — |
| | 3 | <10% T | <40% T | A | B | B | 1500 |

In the method according to the embodiment of the present invention, the violet pigment (a2) is at least one violet pigment selected from C.I. Pigment Violet 19, C.I. Pigment Violet 23, and C.I. Pigment Violet 29.

The method according to the method according to the embodiment of the present invention, the radiation-sensitive composition further includes (B) a polymer, (C) a polyfunctional monomer, and (D) a photoinitiator, the polymer (B) being an alkali-soluble polymer.

In the radiation-sensitive composition according to the embodiment of the present invention, the violet pigment (a2) is at least one violet pigment selected from C.I. Pigment Violet 19, C.I. Pigment Violet 23, and C.I. Pigment Violet 29.

The radiation-sensitive composition according to the embodiment of the present invention further includes (B) a polymer, (C) a polyfunctional monomer, and (D) a photoinitiator, the polymer (B) being an alkali-soluble polymer.

In the method according to the embodiment of the present invention, the immobilizing substance is polylysine, collagen, laminin, a sialic acid-containing oligosaccharide, mannose-binding lectin, an integrin family ligand, a peptide, an antigen, an antibody, or a nucleic acid.

In the method according to the embodiment of the present invention, the target substance is a biological substance.

According to the above method of producing a microarray substrate, adhesion between the partition and the substrate and the water resistance of the partition can be improved while optically isolating the areas defined by the partition.

When the violet pigment (a2) is at least one violet pigment selected from C.I. Pigment Violet 19, C.I. Pigment Violet 23, and C.I. Pigment Violet 29, adhesion between the partition and the substrate and the water resistance of the partition can be further improved while more advantageously optically isolating the areas defined by the partition.

When the radiation-sensitive composition further includes the polymer (B), the polyfunctional monomer (C), and the photoinitiator (D), and the polymer (B) is an alkali-soluble polymer, excellent adhesion and water resistance can be achieved.

The above radiation-sensitive composition can produce a partition of a microchip substrate (that may be used in biochip applications) that exhibits excellent adhesion to a substrate (substrate that forms a microchip substrate) and excellent water resistance while optically isolating the areas defined by the partition.

When the violet pigment (a2) is at least one violet pigment selected from C.I. Pigment Violet 19, C.I. Pigment Violet 23, and C.I. Pigment Violet 29, adhesion between the partition and the substrate and the water resistance of the partition can be further improved while more advantageously optically isolating the areas defined by the partition.

When the radiation-sensitive composition further includes the polymer (B), the polyfunctional monomer (C), and the photoinitiator (D), and the polymer (B) is an alkali-soluble polymer, excellent adhesion and water resistance can be achieved.

The above partition of a microchip substrate (that may be used in biochip applications) exhibits excellent adhesion to a substrate (substrate that forms a microchip substrate) and excellent water resistance while optically isolating the areas defined by the partition.

The above method of producing a biochip can produce a biochip in which adhesion between the partition and the substrate and the water resistance of the partition are improved while optically isolating the areas defined by the partition.

The above biochip is characterized in that adhesion between the partition and the substrate and the water resistance of the partition are improved while optically isolating the areas defined by the partition.

Note that the invention is not limited to the above embodiments and examples. Various modifications and variations may be appropriately made without departing from the scope of the invention depending on the objective and the application.

Obviously, numerous modifications and variations of the invention are possible in light of the above teachings. It is therefore to be understood that within the scope of the appended claims, the invention may be practiced otherwise than as specifically described herein.

What is claimed as new and desired to be secured by Letters Patent of the United States is:

1. A method of producing a microarray substrate that includes a substrate, a partition that is formed on a surface of the substrate, and an area that is positioned over the substrate and defined by the partition, the method comprising:
forming a first film on the substrate using a radiation-sensitive composition comprising a coloring agent (A) comprising at least one of a compound (a1) shown by a formula (1) and a violet pigment (a2); and
patterning the first film by lithography to form the partition, 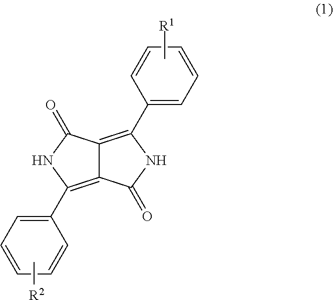
wherein each of R¹ and R² represents one of a hydrogen atom, a halogen atom, an alkyl group having 1 to 10 carbon atoms, a perfluoroalkyl group having 1 to 10 carbon atoms, and an amino group having 0 to 5 carbon atoms.

2. The method according to claim 1, wherein the violet pigment (a2) comprises at least one of C.I. Pigment Violet 19, C.I. Pigment Violet 23, and C.I. Pigment Violet 29.

3. The method according to claim 1, wherein the radiation-sensitive composition further comprises a polymer (B), a polyfunctional monomer (C), and a photoinitiator (D), the polymer (B) comprising an alkali-soluble polymer.

4. A radiation-sensitive composition that is used to form a partition of a microarray substrate that includes a substrate, a partition that is formed on a surface of the substrate, and an area that is positioned over the substrate and defined by the partition, the radiation-sensitive composition comprising:
a coloring agent (A) comprising at least one of a compound (a1) shown by a formula (1) and a violet pigment (a2), 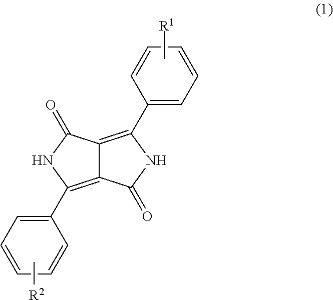
wherein each of R¹ and R² represents one of a hydrogen atom, a halogen atom, an alkyl group having 1 to 10 carbon atoms, a perfluoroalkyl group having 1 to 10 carbon atoms, and an amino group having 0 to 5 carbon atoms.

5. The radiation-sensitive composition according to claim 4, wherein the violet pigment (a2) comprises at least one of C.I. Pigment Violet 19, C.I. Pigment Violet 23, and C.I. Pigment Violet 29.

6. The radiation-sensitive composition according to claim 4, further comprising a polymer (B), a polyfunctional monomer (C), and a photoinitiator (D), the polymer (B) comprising an alkali-soluble polymer.

7. A partition of a microarray substrate produced using the radiation-sensitive composition according to claim 4.

8. A method of producing a biochip, comprising:
producing a microarray substrate using the method according to claim 1;
placing an immobilizing substance configured to immobilize a target substance in an area of the microarray substrate; and
immobilizing the target substance on the immobilizing substance.

9. A method of producing a biochip, comprising:
producing a microarray substrate using the method according to claim 1; and
placing a carrier substance in an area of the microarray substrate, the carrier substance carrying a target substance on a surface of the carrier substance.

10. The method according to claim 8, wherein the immobilizing substance comprises at least one of polylysine, collagen, laminin, a sialic acid-containing oligosaccharide, mannose-binding lectin, an integrin family ligand, a peptide, an antigen, an antibody, and a nucleic acid.

11. The method according to claim 8, wherein the target substance comprises a biological substance.

12. A biochip produced by the method according to claim 8.

13. The method according to claim 2, wherein the radiation-sensitive composition further comprises a polymer (B), a polyfunctional monomer (C), and a photoinitiator (D), the polymer (B) comprising an alkali-soluble polymer.

14. The method according to claim 9, wherein the target substance comprises a biological substance.

15. The method according to claim 10, wherein the target substance comprises a biological substance.

16. A biochip produced by the method according to claim 9.

17. A biochip produced by the method according to claim 10.

18. A biochip produced by the method according to claim 11.
